(19) United States
(12) Patent Application Publication
(10) Pub. No.: US 2012/0256068 A1
(43) Pub. Date: Oct. 11, 2012

(54) ELECTRONIC DEVICE SUPPORTING BASE

(76) Inventor: Pei-Chi SU, Kaohsiung City (TW)

(21) Appl. No.: 13/081,291

(22) Filed: Apr. 6, 2011

(51) Int. Cl. H05K 7/00

(52) U.S. Cl. 248/288.11

(57) ABSTRACT

An electronic device supporting base including a supporting bracket and a fixed base is provided. A first pivoting portion for being pivoted to the fixed base is disposed at one end of the supporting bracket, a second pivoting portion for being pivoted to a positioning plate is disposed at the other end of the supporting bracket, and an accommodating groove is disposed on the fixed base for insertion of an electronic device therein, so that when the electronic device is obliquely placed on a tabletop, the supporting bracket and the positioning plate can be rotated to support the electronic device, and when the electronic device is carried, the supporting bracket and the positioning plate can be rotated to be flatly attached to the back side of the electronic device.

### BACKGROUND OF THE INVENTION

1. Field of Invention

The present invention relates to an electronic product supporting base, and more particularly to an electronic product supporting base convenient to carry and applicable to tablet personal computers (PCs) and portable touch electronic products of different sizes.

2. Related Art

Tablet PCs and portable touch electronic products have the advantage of being light and convenient to carry. In the case that the operation performance and battery duration have been significantly increased, such products have gradually played an important role in the market and will become mainstream products in the future.

For the convenience of long time use, a user can obliquely place a tablet PC or a portable touch electronic product on a tabletop with a dedicated supporting bracket. However, to achieve the effect of stable supporting, the conventional dedicated supporting bracket is usually heavy and big, thereby causing a disadvantage of inconvenient carrying. Moreover, the design of the dedicated supporting bracket is only applicable to tablet PCs or portable touch electronic products of a specific size. If a tablet PC or a portable touch electronic product of a larger size than that of the supporting bracket is placed on the supporting bracket, the tablet PC or the portable touch electronic product is turned over easily since a touching position exceeds the dedicated supporting bracket. Furthermore, if a tablet PC or a portable touch electronic product of a smaller size than that of the supporting bracket is placed on the supporting bracket, it is not convenient to fetch or move the tablet PC or the portable touch electronic product. Therefore, the tablet PCs or the portable touch electronic products of different sizes cannot be used on a single conventional dedicated supporting bracket.

Accordingly, in order to overcome the disadvantages so that the electronic device supporting base is applicable to the tablet PCs and the portable touch electronic products of different sizes and easy to carry, the inventor makes the present invention based on many years' experience through continuous research, development, and improvement.

### SUMMARY OF THE INVENTION

The primary object of the present invention is to provide an electronic device supporting base, in which a fixed base having an accommodating groove is pivotally disposed at one end of a supporting bracket, and the supporting bracket is pivoted to the fixed base at an adjustable fixed angle, so that when an electronic device is inserted into the accommodating groove, the supporting bracket can be rotated with respect to the electronic device, and when the electronic device is obliquely placed on a plane, the electronic device can be supported at various angles.

Another object of the present invention is to provide an electronic device supporting base, in which a positioning plate is pivotally disposed at the other end of the supporting bracket, and the supporting bracket is pivoted to the positioning plate at an adjustable fixed angle, so that when the supporting bracket supports an electronic device on a plane, an oblique angle of the electronic device on the plane can be adjusted by adjusting an angle between the positioning plate and the supporting bracket.

To achieve the above objectives, the present invention provides an electronic device supporting base, which includes a supporting bracket and a fixed base. A first pivoting portion for being pivoted to the fixed base is disposed at one end of the supporting bracket, a second pivoting portion is disposed at the other end of the supporting bracket, and an accommodating groove is disposed on the fixed base for insertion of an electronic device therein, so that the supporting bracket can be rotated with respect to the electronic device.

In practice, a plurality of recesses is further disposed on a surface of the first pivoting portion, and a plurality of protrusions for snapping the recesses is further disposed at a position of the fixed base pivoted to the first pivoting portion.

In practice, a positioning plate is pivoted to the second pivoting portion.

In practice, the second pivoting portion further has a positioning hole disposed on an end surface of the supporting bracket, and at least one protrusion for snapping the positioning hole is further disposed at a position of the positioning plate pivoted to the second pivoting portion.

In practice, a stopping portion extends from the positioning plate to restrict a rotation position of the positioning plate.

Other objects, advantages and novel features of the present invention will become more apparent from the following detailed description when taken in conjunction with the accompanying drawings.

### BRIEF DESCRIPTION OF THE DRAWINGS

FIG. 1 is a schematic exploded view of a first embodiment of the present invention;

FIG. 2 is a perspective view of the embodiment in FIG. 1;

FIG. 3 is a schematic view illustrating the operation in which a supporting bracket is rotated with respect to a fixed base in the embodiment of FIG. 1;

FIG. 4 is a schematic view illustrating the operation in which a positioning plate is rotated with respect to the supporting bracket in the embodiment of FIG. 1;

FIG. 5 is a schematic view in which an electronic device supporting base in the embodiment of FIG. 1 is disposed at two sides of an electronic device;

FIG. 6 is a schematic view in which the electronic device supporting base in the embodiment of FIG. 1 is disposed at an upper side edge of the electronic device;

FIG. 7 is a schematic back outside view in which the electronic device supporting base in the embodiment of FIG. 1 is disposed at the upper side edge of the electronic device;

FIG. 8 is a perspective of a second embodiment of the present invention; and

FIG. 9 is a perspective of a third embodiment of the present invention.

FIG. 10A is a perspective of a fourth embodiment of the present invention.

FIG. 10B is a schematic exploded view of the fourth embodiment of the present invention.

### DETAILED DESCRIPTION OF THE INVENTION

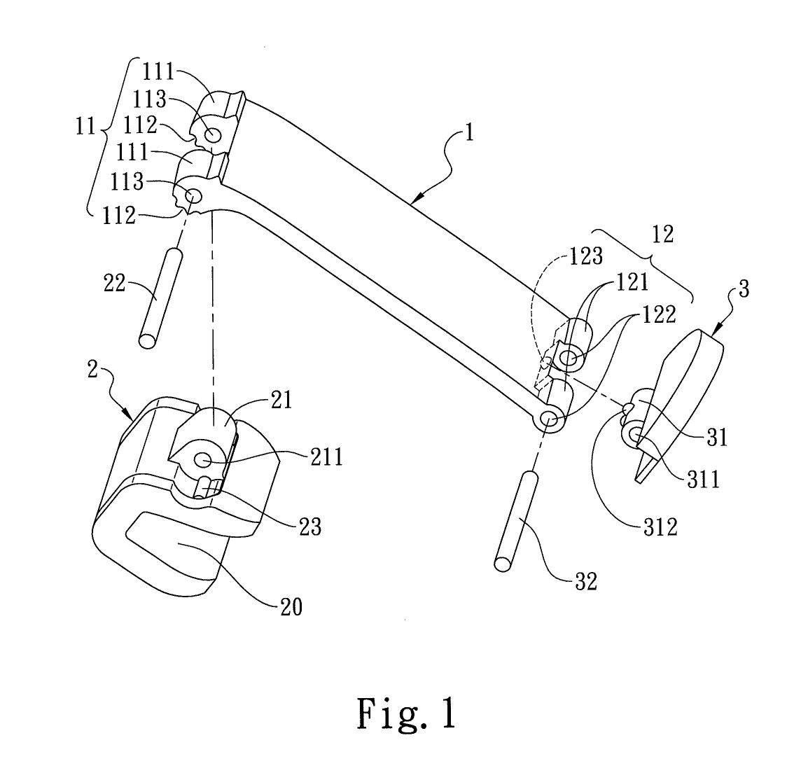

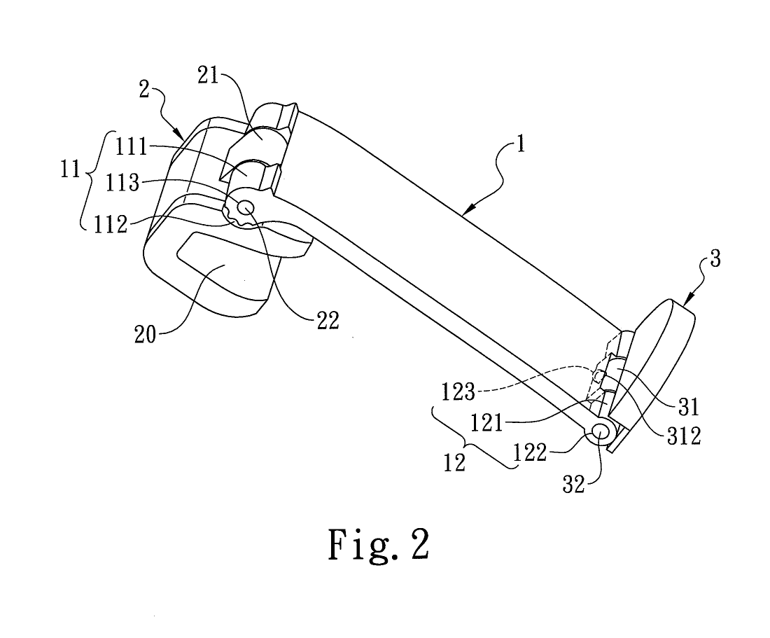

Referring to FIGS. 1 and 2, a first embodiment of an electronic device supporting base according to the present invention is shown, which includes a supporting bracket 1, a fixed base 2, and a positioning plate 3.

A first pivoting portion 11 and a second pivoting portion 12 are respectively disposed at two ends of the supporting bracket 1. The first pivoting portion 11 includes two lugs 111, an accommodating space is formed between the two lugs 111, a plurality of recesses 112 is successively arranged on an external surface of each lug 111, and an axial perforation 113 is disposed in each lug 111. The second pivoting portion 12 includes two lugs 121, an accommodating space is formed between the two lugs 121, and an axial perforation 122 is disposed in each lug 121. Moreover, the second pivoting portion 12 has a positioning hole 123 disposed at an end surface of the supporting bracket 1 between the two lugs 121.

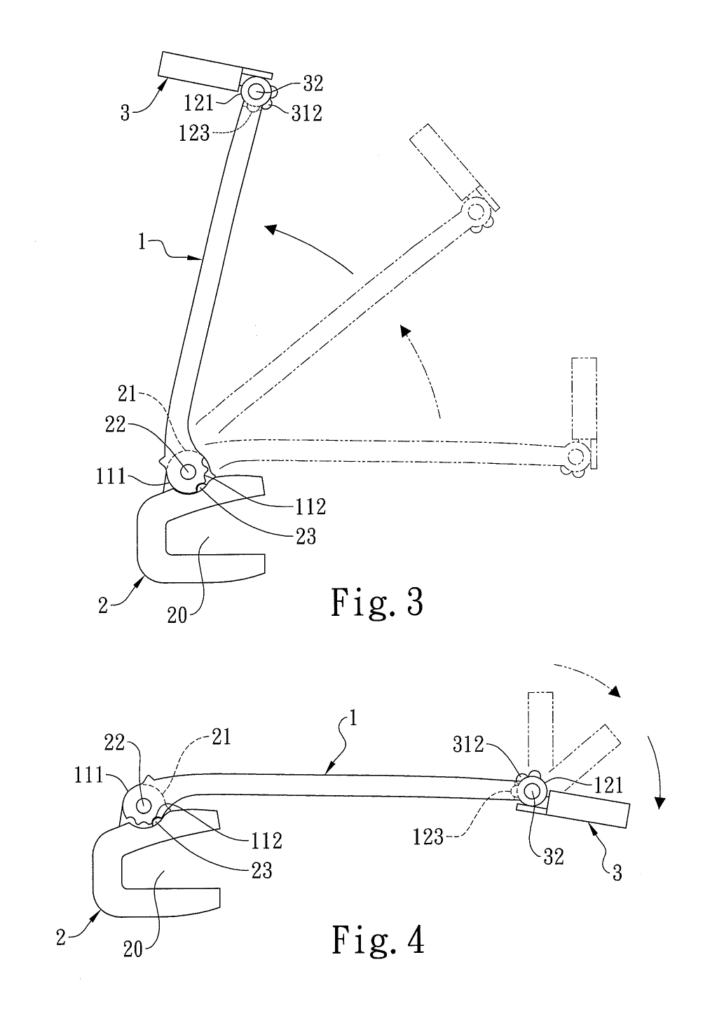

The fixed base 2 is a substantially U-shaped structure, and an accommodating groove 20 is formed on the fixed base 2. A lug 21 is disposed at the center of one of lateral surfaces of the fixed base 2 and has an axial perforation 211, so that when the lug 21 is inserted between the two lugs 111 of the first pivoting portion 11, a pin 22 can be inserted into the perforations (211, 113) of the lugs (21, 111) to pivot the fixed base 2 to the supporting bracket 1, thus enabling the supporting bracket 1 to be rotated with respect to the fixed base 2 (as shown in FIG. 3). Moreover, the fixed base 2 has a protrusion 23 disposed respectively at left and right sides of the lug 21, for snapping the recess 112 on one of the two lugs 11 when the lug 21 is inserted between the two lugs 11 of the first pivoting portion 11, so as to fix the relative position between the fixed base 2 and the supporting bracket 1.

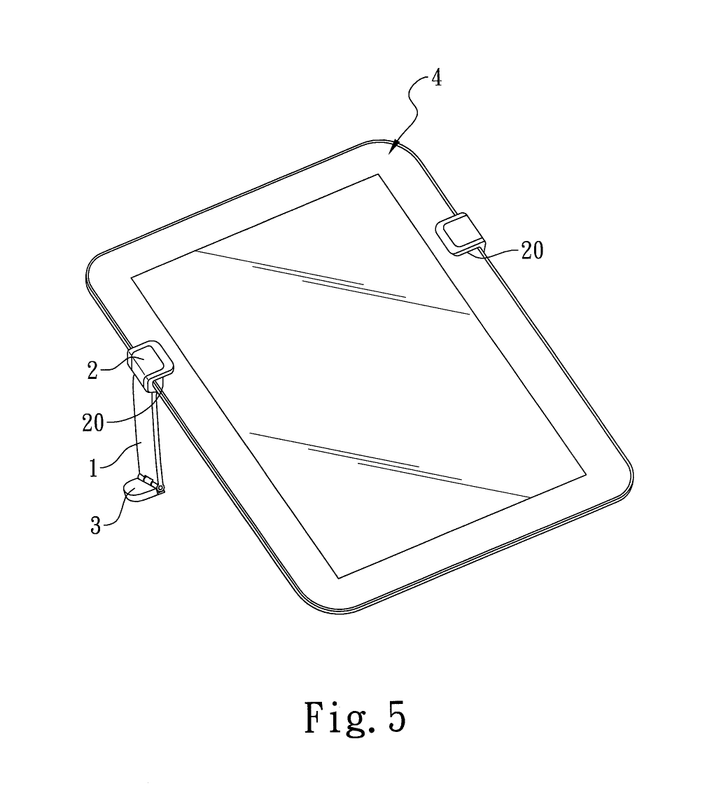

A lug 31 is disposed at one end of the positioning plate 3 and has an axial perforation 311, so that when the lug 31 of the positioning plate 3 is inserted between the two lugs 121 of the second pivoting portion 12, a pin 32 can be inserted into the perforations (311, 122) of the lugs (31, 121) to pivot the positioning plate 3 to the supporting bracket 1, thus enabling the positioning plate 3 to be rotated with respect to the supporting bracket 1 (as shown in FIG. 4). A plurality of protrusions 312 for snapping the positioning hole 123 of the second pivoting portion 12 is disposed on a surface of the lug 31, so that when the lug 31 is inserted between the two lugs 121 of the second pivoting portion 12, one of the protrusions 312 can snap the positioning hole 123, so as to fix the relative position between the positioning plate 3 and the supporting bracket 1. Moreover, the positioning plate 3 has a stopping portion extending from one side of the lug 31, for restricting the rotation of the positioning plate 3 to one side surface of the supporting bracket 1 when the positioning plate 3 is rotated.

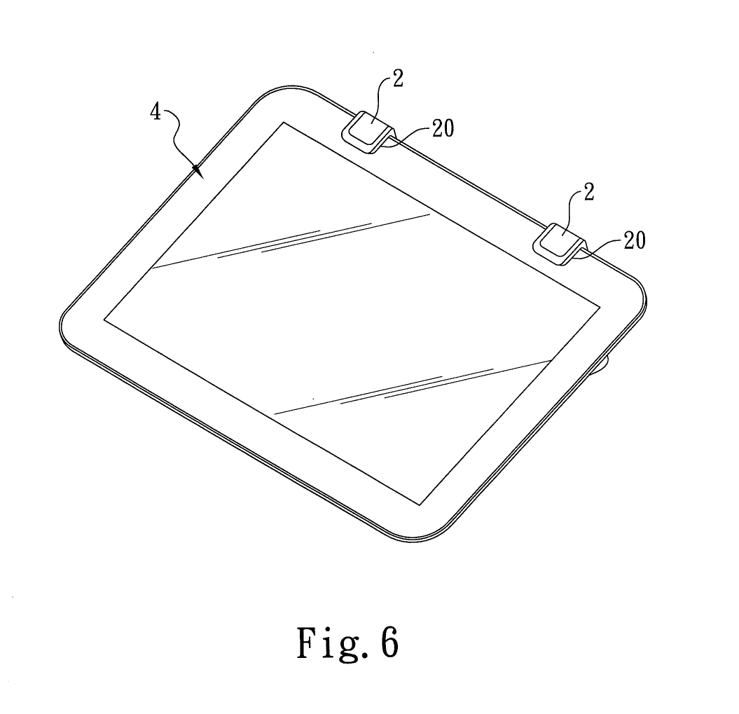

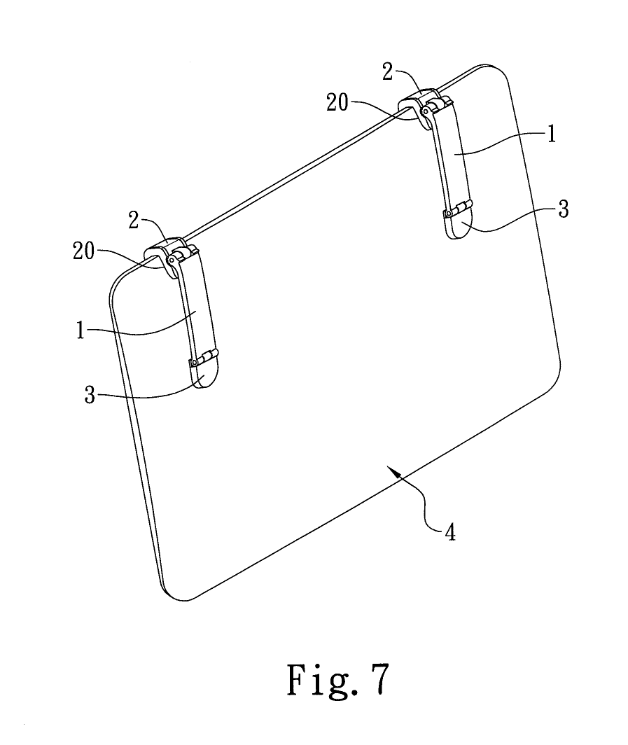

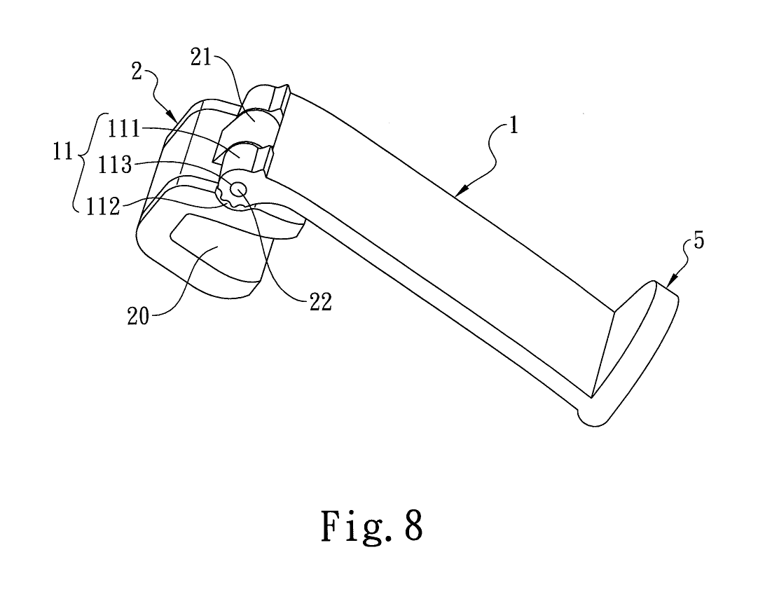

In practice, a left side edge and a right side edge of an electronic device 4 (for example, a tablet PC or a portable touch electronic product) can be respectively inserted into the accommodating groove 20 of the electronic device supporting base of the present invention (as shown in FIG. 5), or a left end and a right end of one side edge of the electronic device 4 can be respectively inserted into the accommodating groove 20 of the electronic device supporting base of the present invention (as shown in FIG. 6), and the supporting bracket 1 and the positioning plate 3 is rotated to an appropriate angle, so that the electronic device is stably supported on a plane such as a tabletop with the electronic device supporting base of the present invention. When the electronic device 4 with the electronic device supporting base of the present invention is carried, the supporting bracket 1 and the positioning plate 3 can be rotated to be flatly attached to the back side of the electronic device 4 (as shown in FIG. 7).

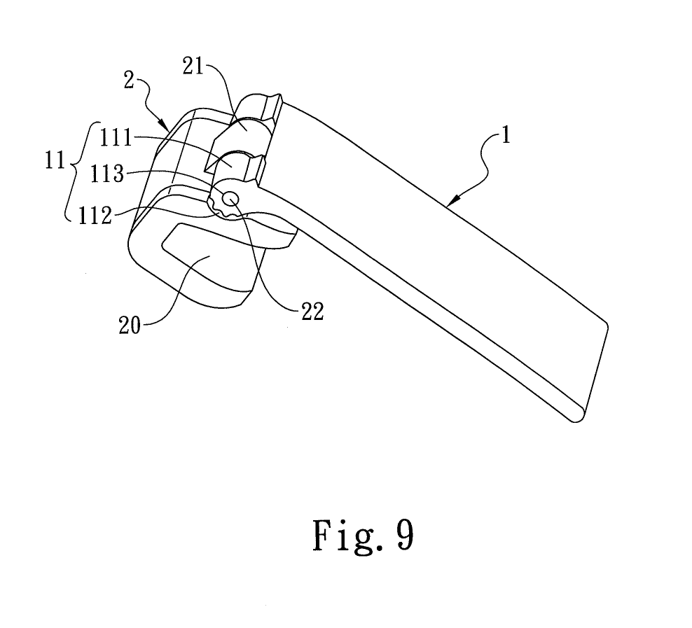

Referring to FIG. 8, a second embodiment of the electronic device supporting base according to the present invention is shown. Based on the structure of the first embodiment, a supporting plate 5 extends from the other end of the supporting bracket opposite to the first pivoting portion 11, and is disposed at the distal end of the supporting bracket 1 perpendicularly to the supporting bracket 1, so that when the electronic device supporting base of the present invention supports an electronic device obliquely placed on a tabletop, the contact area of the supporting bracket and the tabletop is increased, thereby improving the supporting stability.

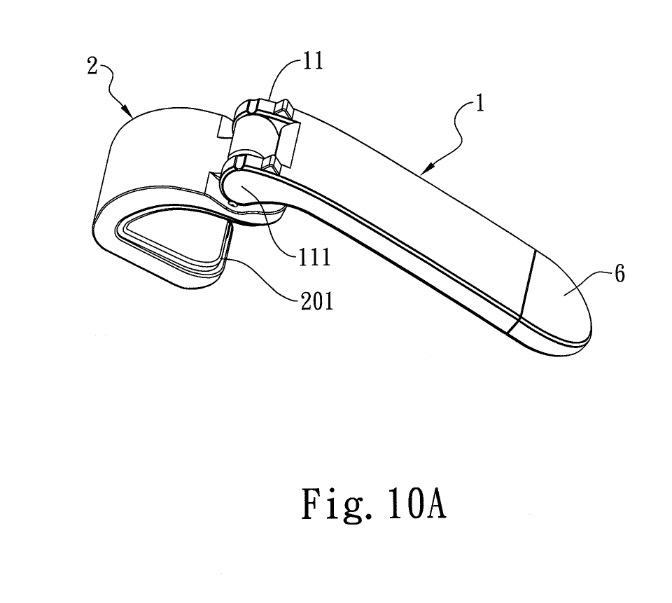

Referring to FIG. 9, a third embodiment of the electronic device supporting base according to the present invention is shown. Based on the structure of the first embodiment, one end of the supporting bracket 1 is pivoted to the fixed base 2, and the other end of the supporting bracket 1 is a sheet structure, so that when the electronic device with the electronic device supporting base of the present invention is carried, the supporting bracket can be flatly attached to the back side of the electronic device.

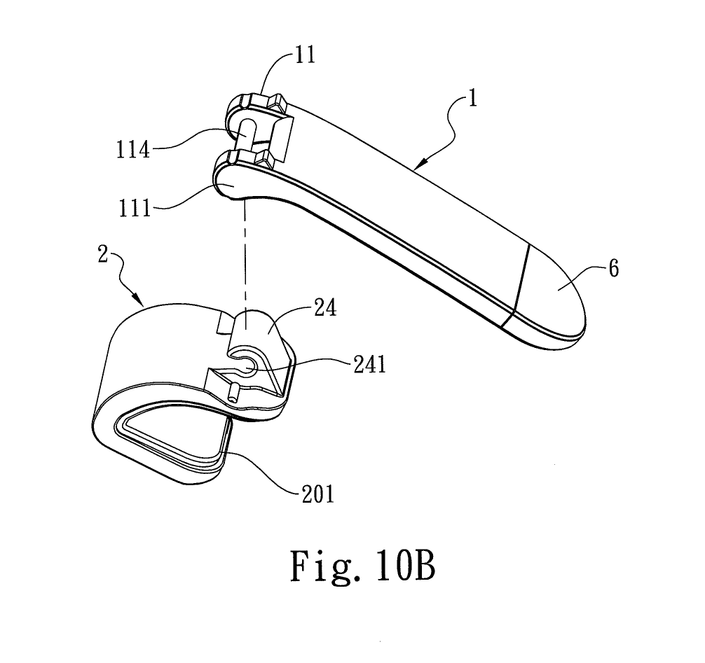

Referring to FIG. 10A-10B, a fourth embodiment of the electronic device supporting base according to the present invention is shown. Based on the structure of the first embodiment, a pivoting shaft 114 is disposed between the two lugs 111 of the first pivoting portion 11, and a fastening groove 241 is disposed at the lug 24 of the fixed base 2, thus enabling the supporting bracket 1 to be rotated with respect to the fixed base 2 when the pivoting shaft 114 is disposed in the fastening groove 241. A rubber protective mat 201 is disposed in the accommodating groove 20 of the fixed base 2 for preventing the edge of electronic device from being scraped when it is inserted into the accommodating groove 2. Further, a rubber sheet 6 is disposed at the other end of the supporting bracket 1 for preventing the tabletop or the back side of the electronic device from being scraped.

Accordingly, the present invention has the following advantages.

1. The installation position of the electronic device supporting base of the present invention on the periphery of the electronic device can be changed as required, which can avoid turning over the electronic device due to a too great touch force, so that the electronic device is stably placed on the tabletop obliquely.

2. In the present invention, an oblique angle of the electronic device on the tabletop can be adjusted to a desirable angle for viewing by changing a fixed angle between the supporting bracket and the fixed base.

3. The electronic device supporting base of the present invention is small, light, and convenient to carry, can be directly applied to electronic devices of different sizes without affecting the original handheld operating mode of the electronic devices, and can be installed on the electronic devices for a long time, so as to improve the practicability.

To sum up, as described above, the present invention can achieve the intended purpose, which is to provide an electronic device supporting base that is applicable to tablet PCs and portable touch electronic products of different sizes and is convenient to carry and use, and has industrial applicability, so an application for a patent for utility model is filed according to the law.

It should be understood that different modifications and variations could be made from the disclosures of the present invention by the people familiar in the art without departing the spirit of the present invention.

What is claimed is:

1. An electronic device supporting base, comprising:
a supporting bracket, wherein a first pivoting portion is disposed at one end of the supporting bracket; and
a fixed base, pivoted to the first pivoting portion, wherein the fixed base has an accommodating groove for insertion of an electronic device therein, so that the supporting bracket is capable of being rotated with respect to the electronic device.

2. The electronic device supporting base according to claim 1, wherein a plurality of recesses is further disposed on a surface of the first pivoting portion, and a plurality of protrusions for snapping the recesses is further disposed at a position of the fixed base pivoted to the first pivoting portion.

3. The electronic device supporting base according to claim 1, wherein a second pivoting portion is further disposed at the other end of the supporting bracket, and a positioning plate is pivoted to the second pivoting portion.

4. The electronic device supporting base according to claim 3, wherein the second pivoting portion further has a positioning hole disposed on an end surface of the supporting bracket, and at least one protrusion for snapping the positioning hole is further disposed at a position of the positioning plate pivoted to the second pivoting portion.

5. The electronic device supporting base according to claim 3, wherein a stopping portion extends from the positioning plate to restrict a rotation position of the positioning plate.

6. The electronic device supporting base according to claim 1, wherein a supporting plate is further disposed at the other end of the supporting bracket.

7. The electronic device supporting base according to claim 1, wherein a protective mat is further disposed in the accommodating groove of the fixed base.

8. The electronic device supporting base according to claim 1, wherein the protective mat is made of rubber.

9. The electronic device supporting base according to claim 1, wherein a rubber sheet is further disposed at the other end of the supporting bracket.
